(19) United States
(12) Patent Application Publication
(10) Pub. No.: US 2026/0190903 A1
(43) Pub. Date: Jul. 2, 2026

(54) TREATMENT CONTAINER AND SUBSTRATE TREATMENT APPARATUS INCLUDING TREATMENT CONTAINER

(71) Applicant: SEMES CO., LTD., Cheonan-si (KR)

(72) Inventor: Chang Suk OH, Cheonan-si (KR)

(21) Appl. No.: 19/370,900

(22) Filed: Oct. 28, 2025

(30) Foreign Application Priority Data
Dec. 27, 2024 (KR) 10-2024-0198499

(51) Int. Cl. H10P 72/00; B08B 15/02

(52) U.S. Cl. CPC H10P 72/0414; B08B 15/02

(57) ABSTRACT

A substrate treatment apparatus includes a treatment container having an internal space, a support portion provided in the internal space, the support portion configured to support the substrate, and a cleaning unit provided in the internal space, the cleaning unit configured to spray a treatment liquid toward a rear surface of the substrate. The treatment container includes a lower cup having a lower surface having a rectangular shape and an open upper portion, an upper cup coupled to the lower cup to form the internal space, and a vortex prevention unit disposed between the lower cup and the upper cup. The vortex prevention unit includes a plurality of blade layers in which an outer radius of a lower layer is less than an outer radius of an upper layer.

### CROSS-REFERENCE TO RELATED APPLICATION(S)

This application claims benefit of priority to Korean Patent Application No. 10-2024-0198499 filed on December 27, 2024 in the Korean Intellectual Property Office, the disclosure of which is incorporated herein by reference in its entirety.

### TECHNICAL FIELD

The present disclosure relates to a treatment container and a substrate treatment apparatus including the same.

In general, a manufacturing process of a substrate for a semiconductor may be subdivided into a thin film process of depositing a thin film on a glass substrate, a photolithography process of forming the thin film into a desired pattern, and an etching process of etching the thin film according to the pattern. By repeatedly performing such processes, a substrate for a semiconductor may be manufactured.

In addition, a manufacturing process of a substrate for a semiconductor may include a cleaning process of cleaning the substrate by spraying a cleaning liquid onto the substrate.

In such a cleaning process, there is a need for a structure of a treatment container capable of easily recovering a cleaning liquid scattering in the treatment container within a housing. In addition, in the case of a treatment container in the form of a rectangular bath, in the related art, two exhaust ports for exhausting mist in the treatment container may be disposed, such that mist may stagnate at rectangular corners of the treatment container, which may cause contamination of an upper surface of a substrate. Accordingly, in the treatment container in the form of a rectangular bath, there is a need for a structure capable of easily exhausting an airflow in the treatment container or a treatment liquid.

### SUMMARY

An aspect of the present disclosure is to provide a structure of a treatment container capable of easily recovering a cleaning liquid scattering in the treatment container and easily exhausting an airflow in the treatment container and the recovered treatment liquid.

The aspects of the present disclosure are not limited thereto, and it may be understood by those skilled in the art that other technical issues not mentioned may be derived from the configurations described in the following specification and drawings.

According to an aspect of the present disclosure, there is provided a substrate treatment apparatus including a treatment container having an internal space, a support portion provided in the internal space, the support portion configured to support the substrate, and a cleaning unit provided in the internal space, the cleaning unit configured to spray a treatment liquid toward a rear surface of the substrate. The treatment container may include a lower cup having a lower surface having a rectangular shape and an open upper portion, an upper cup coupled to the lower cup to form the internal space, and a vortex prevention unit disposed between the lower cup and the upper cup. The vortex prevention unit may include a plurality of blade layers in which an outer radius of a lower layer is less than an outer radius of an upper layer.

According to another aspect of the present disclosure, there is provided a treatment container having an internal space, the treatment container including a lower cup having a lower surface having a rectangular shape and an open upper portion, an upper cup coupled to the lower cup to form the internal space, and a vortex prevention unit disposed between the lower cup and the upper cup. The vortex prevention unit may include a plurality of blade layers. The vortex prevention unit may include a plurality of blade layers in which an outer radius of a lower layer is less than an outer radius of an upper layer.

According to another aspect of the present disclosure, there is provided a substrate treatment apparatus including a treatment container having an internal space, a support portion provided in the internal space, the support portion configured to support a substrate, and a cleaning unit provided in the internal space, the cleaning unit configured to spray a treatment liquid toward a rear surface of the substrate. The treatment container may include a lower cup having a lower surface having a rectangular shape and an open upper portion, an upper cup coupled to the lower cup to form the internal space, and a vortex prevention unit disposed between the lower cup and the upper cup. The vortex prevention unit may include a plurality of blade layers in which an outer radius of a lower layer is less than an outer radius of an upper layer, each of the plurality of blade layers formed of a band having a predetermined inclination, the band inclined downwardly from a central portion thereof toward an outer portion thereof, and a fixing member intersecting the plurality of blade layers stacked in a vertical direction, the fixing member configured to fix the plurality of blade layers. The fixing member may have a lower end biased in a rotational direction of the substrate, and thus may have a predetermined inclination.

According to example embodiments of the present disclosure, a structure of a treatment container may easily recover a cleaning liquid scattering in the treatment container and easily exhaust an airflow in the treatment container and the recovered treatment liquid.

The effects of the present disclosure are not limited to the above-described effects, and it may be understood by those skilled in the art that other effects not mentioned herein may be derived from the configurations described in the following specification and drawings.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a top view of a substrate treatment apparatus according to an example embodiment of the present disclosure;

FIG. 2 is a view of the substrate treatment apparatus of FIG. 1 taken along line A-A;

FIG. 3 is a view of the substrate treatment apparatus of FIG. 1 taken along line B-B;

FIG. 4 is a schematic front cross-sectional view of a substrate treatment apparatus according to an example embodiment of the present disclosure;

FIG. 5 is a schematic exploded front cross-sectional view of a treatment container according to an example embodiment of the present disclosure;

FIG. 6 is a schematic exploded perspective view of a treatment container according to an example embodiment of the present disclosure;

FIG. 7 is an enlarged view of a portion of FIG. 4; and

FIG. 8 is an enlarged view of a portion of FIG. 4.

### DETAILED DESCRIPTION

Hereinafter, preferred example embodiments will be described in detail, such that the disclosure could be easily carried out. In describing example embodiments of the present disclosure, when it is determined that a detailed description of a known technology related to the present disclosure may unnecessarily obscure the gist of the present disclosure, a detailed description thereof will be omitted. In addition, the same reference numerals are used throughout the drawings with respect to components having similar functions and actions. In addition, in the present specification, terms such as “upper,” “upper portion,” “upper surface,” “lower,” “lower portion,” “lower surface,” and “side surface” are based on the drawings, may vary depending on a direction in which an element or component is actually arranged.

In addition, it will be understood that “comprises,” “comprising,” “includes,” and “including” specify the presence of stated features, integers, operations, operations, elements, components or a combination thereof, but do not preclude the presence or addition of one or more other features, integers, operations, operations, elements, components, and/or groups thereof.

The present disclosure may be implemented in various forms, and is not limited to the example embodiments described herein.

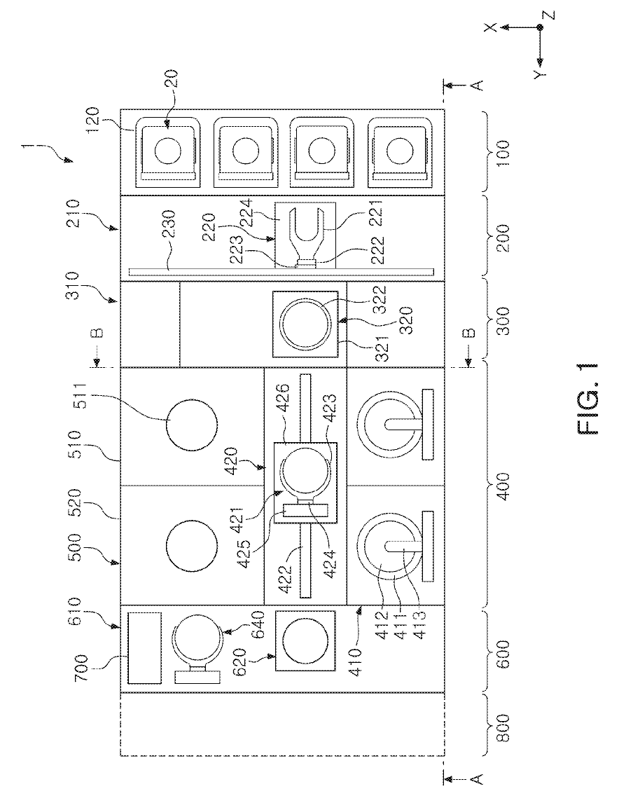

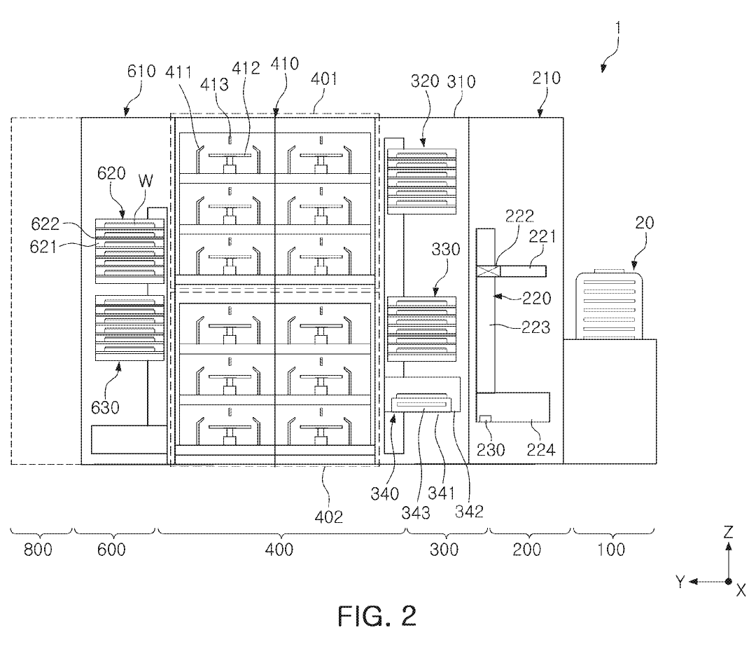

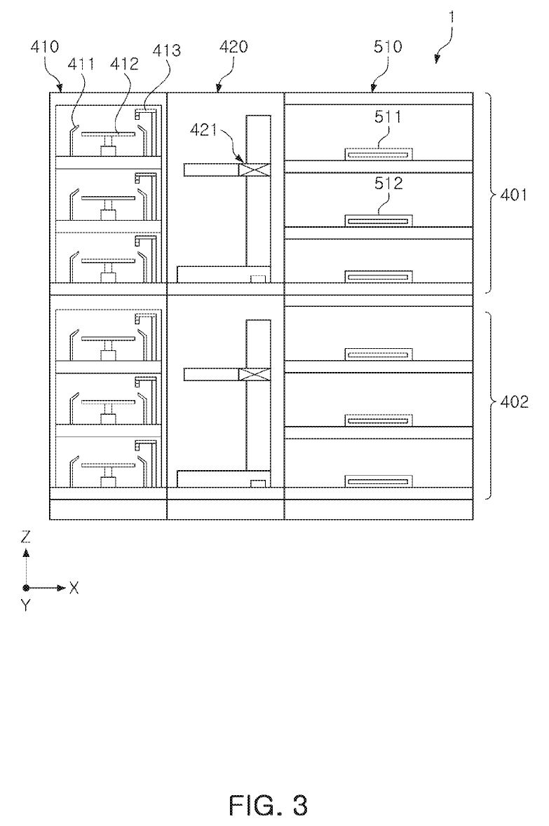

FIG. 1 is a top view of a substrate treatment apparatus according to an example embodiment of the present disclosure. FIG. 2 is a view of the substrate treatment apparatus of FIG. 1 taken along line A-A. FIG. 3 is a view of the substrate treatment apparatus of FIG. 1 taken along line B-B.

Referring to FIGS. 1 to 3, a substrate treatment apparatus 1 may include a load port 100, an index module 200, a buffer module 300, a coating and development module 400, and a purge module 700. The load port 100, the index module 200, the buffer module 300, the coating and development module 400, and an interface module 600 may be sequentially disposed in a line in one direction. The purge module 700 may be provided in the interface module 600. Alternatively, the purge module 700 may be provided in various positions such as a position to which an exposure device 800 at a rear end of the interface module 600 is connected, a side portion of the interface module 600, or the like.

Hereinafter, a direction in which the load port 100, the index module 200, the buffer module 300, the coating and development module 400, and the interface module 600 are disposed may be referred to as a first direction Y, a direction, perpendicular to the first direction Y when viewed from above, may be referred to as a second direction X, and a direction, perpendicular to each of the first direction Y and the second direction X, may be referred to as a third direction.

The substrate W may be moved in a state of being accommodated in a cassette 20. The cassette 20 may be sealed externally. As one example, a front open integrated pod (FOUP), having a door in front thereof, may be used as the cassette 20.

Hereinafter, the load port 100, the index module 200, the buffer module 300, the coating and development module 400, the interface module 600, and the purge module 700 will be described in detail.

The load port 100 may have a mounting table 120 on which the cassette 20 in which the substrate W is accommodated is disposed. The mounting table may be provided as a plurality of mounting tables 120, and the mounting tables 120 may be disposed in a line in the second direction X. FIG. 2 illustrates an example in which four mounting tables 120 are provided, but the number of mounting tables 120 may be changed.

The index module 200 may transfer the substrate W between the cassette 20 disposed on the mounting table 120 of the load port 100 and the buffer module 300. The index module 200 may include a frame 210, an index robot 220, and a guide rail 230. The frame 210 may have a substantially rectangular parallelepiped shape having an empty space therein, and may be disposed between the load port 100 and the buffer module 300. The frame 210 of the index module 200 may have a height, lower than that of a frame 310 of the buffer module 300. The index robot 220 and the guide rail 230 may be disposed in the frame 210. The index robot 220 may be provided such that a hand 221, directly handling the substrate W, is movable and rotatable in the first direction Y, the second direction X, and the third direction Z. The index robot 220 may include a hand 221, an arm 222, a support 223, and a pedestal 224. The hand 221 may be fixedly installed on the arm 222. The arm 222 may have a stretchable structure and a rotatable structure. The support 425 may be disposed such that a length direction thereof is the same as the third direction Z. The arm 222 may be coupled to the support 223 to be movable along the support 223. The support 223 may be fixedly coupled to the pedestal 224. The guide rail 230 may be disposed such that a length direction thereof is the same as the second direction X. The pedestal 224 may be coupled to the guide rail 230 to be linearly movable along the guide rail 230. In addition, although not illustrated, the frame 210 may further have a door opener for opening and closing a door of the cassette 20.

The buffer module 300 may include a frame 310, a first buffer 320, a second buffer 330, and a cooling chamber 340. The frame 310 may have a rectangular parallelepiped shape having an empty space therein, and may be disposed between the index module 200 and the coating and development module 400. The first buffer 320, the second buffer 330, and the cooling chamber 340 may be positioned in the frame 310. The cooling chamber 340, the second buffer 330, and the first buffer 320 may be sequentially disposed from the bottom in the third direction Z. The first buffer 320 may be positioned to have a height corresponding to that of a coating module 401 of the coating and development module 400, and the second buffer 330 and the cooling chamber 340 may be positioned to have a height corresponding to that of a development module 402 of the coating and development module 400.

The first buffer 320 and the second buffer 330 may temporarily store a plurality of substrates W, respectively. The first buffer 320 may have a housing 321 and a plurality of supports 322. In the first buffer 320, the supports 322 may be disposed in the housing 321, and may be spaced apart from each other in the third direction Z. The second buffer 330 may have a housing 331 and a plurality of supports 332. In the second buffer 330, the supports 332 may be disposed in the housing 331, and may be spaced apart from each other in the third direction Z. One substrate W may be disposed on each support 322 of the first buffer 320 and each support 332 of the second buffer 330. The housing 331 may have an opening in a direction in which the index robot 220 is provided, such that the index robot 220 may carry the substrate W into or out of the support 332 in the housing 331. The first buffer 320 may have a structure substantially similar to that of the second buffer 330. However, the housing 321 of the first buffer 320 may have openings in a direction in which a first buffer robot 360 is provided and in a direction in which a coating portion robot 421 positioned in the coating module 401 is provided. The number of supports 322 provided in the first buffer 320 may be equal to or different from the number of supports 332 provided in the second buffer 330. According to an example, the number of supports 332 provided in the second buffer 330 may be greater than the number of supports 322 provided in the first buffer 320.

The cooling chamber 340 may cool the substrate W. The cooling chamber 340 may include a housing 341 and a cooling plate 342. The cooling plate 342 may have an upper surface on which the substrate W is disposed, and a cooling means 343 for cooling the substrate W. Various methods, such as cooling using coolant or cooling using a thermoelectric element, may be used as the cooling means 343. In addition, the cooling chamber 340 may include a lift pin assembly for positioning the substrate W on the cooling plate 342. The housing 341 may have openings in a direction in which the index robot 220 is provided and in a direction in which a developing portion robot in the development module 402 is provided, such that the index robot 220 and the developing portion robot may carry the substrate W into or out of the cooling plate 342. In addition, doors for opening and closing the above-described openings may be provided in the cooling chamber 340.

In the above-described example embodiments, the buffer module 300 has been described to include the cooling chamber 340, but the present disclosure is not limited thereto. The cooling chamber 340 may be omitted, as necessary.

The coating module 401 may include a process of coating a photosensitive liquid, such as a photoresist, on the substrate W, and a heat treatment process, such as heating and cooling of the substrate W, before and after a resist coating process. The coating module 401 may have a coating chamber 410, a heat treatment chamber portion 500, and a conveyance chamber 420. The coating chamber 410, the conveyance chamber 420, and the heat treatment chamber portion 500 may be sequentially disposed in the second direction X. That is, with respect to the conveyance chamber 420, the coating chamber 410 may be disposed on one side of the conveyance chamber 420, and the heat treatment chamber portion 500 may be disposed on the other side of the conveyance chamber 420.

The coating chamber 410 may be provided as a plurality of coating chambers 410 in the third direction Z. In addition, as illustrated in FIG. 1, the coating chamber 410 may be provided as a plurality of coating chambers 410 in the first direction Y and as one coating chamber 410 in the first direction Y. The heat treatment chamber portion 500 may include a baking chamber 510 and a cooling chamber 520, and the baking chamber 510 and the cooling chamber 520 may be provided as a plurality of baking chambers 510 and a plurality of cooling chambers 520 in the third direction Z, respectively. The conveyance chamber 420 may be positioned to be parallel to the first buffer 320 of buffer module 300 in a first direction 12. The coating portion robot 421 and the guide rail 422 may be positioned in the conveyance chamber 420. The conveyance chamber 420 may have a substantially rectangular shape. The coating portion robot 421 may transfer the substrate W, between the baking chamber 510, the cooling chamber 520, the coating chamber 410, and the first buffer 320 of buffer module 300.

The guide rail 422 may be disposed such that a length direction thereof is parallel to the first direction Y. The guide rail 422 may guide the coating portion robot 421 to linearly move in the first direction Y. The coating portion robot 421 may have a hand 423, an arm 424, a support 425, and a pedestal 426. The hand 423 may be fixedly installed on the arm 424. The arm 424 may have a stretchable structure, such that the hand 423 may move in a horizontal direction. The support 425 may be disposed such that a length direction thereof is the same as the third direction Z. The arm 424 may be coupled to the support 425 so as to be linearly movable in the third direction Z along the support 425. The support 425 may be fixedly coupled to the pedestal 426, and the pedestal 426 may be coupled to the guide rail 422 so as to be movable along the guide rail 422.

All of the coating chambers 410 may have the same structure. However, types of treatment liquids, respectively used in the coating chambers 410, may be different from each other. A treatment liquid for forming a photoresist film or an antireflection film may be used as the treatment liquid.

The coating chamber 410 may coat a treatment liquid on the substrate W. A treatment unit, including a treatment container 411, a support portion 412, and a nozzle portion 413, may be provided in the coating chamber 410.

As one example, one treatment unit may be disposed in each coating chamber 410 in the first direction Y, but the present disclosure is not limited thereto, and two or more treatment units may be disposed in a single coating chamber 410. The treatment units may all have the same structure. However, types of treatment liquids, respectively used in the treatment units, may be different from each other.

The treatment container 411 of the coating chamber 410 may have a shape having an open upper portion. The support portion 412 may be disposed in the treatment container 411, and may support the substrate W. The support portion 412 may be rotatably provided. The nozzle portion 413 may supply a treatment liquid onto the substrate W disposed on the support portion 412. The treatment liquid may be coated on the substrate W in a spin-coating manner. In addition, the coating chamber 410 may further selectively include a nozzle (not illustrated) for supplying a cleaning liquid such as deionized water (DIW) to clean a surface of the substrate W on which the treatment liquid is coated, and a back rinse nozzle (not illustrated) for cleaning a lower surface of the substrate W.

In the baking chamber 510, when the substrate W is mounted by the coating portion robot 421, the substrate W may be heat-treated.

In the baking chamber 510, a pre-baking process of removing organic matter or moisture from a surface of the substrate W by heating the substrate W to a predetermined temperature may be performed before the treatment liquid is coated, or a soft baking process may be performed after the treatment liquid is coated on a wafer W, and a cooling process of cooling the substrate W may be performed after each heating process.

A heating plate 511 and a cooling plate 512 may be provided in the baking chamber 510. A cooling means such as coolant or a thermoelectric element may be provided in the cooling plate 512.

The cooling chamber 520 may perform a cooling process of cooling the substrate W before the treatment liquid is coated. The cooling chamber 520 may include a cooling plate. The cooling plate may include a cooling means in which various methods, such as cooling using a coolant or cooling using a thermoelectric element, are used to cool the substrate W.

The interface module 600 may connect the coating and development module 400 to an external exposure device 800. The interface module 600 may include an interface frame 610, a first interface buffer 620, a second interface buffer 630, and a conveyance robot 640, and the conveyance robot 640 may convey, to the exposure device 800, the substrate conveyed to the first and second interface buffers 620 and 630 after the coating and development module 400 is terminated. The first and second interface buffers 620 may include a housing 621 and a support 622, and the conveyance robot 640 and the coating portion robot 421 may carry the substrate W into/out of the support 622.

Hereinafter, an example embodiment of the present disclosuremay be applicable to a coating chamber 410 according to an example embodiment of the present disclosure, and may also be applicable not only to the coating chamber 410 but also to various types of chambers.

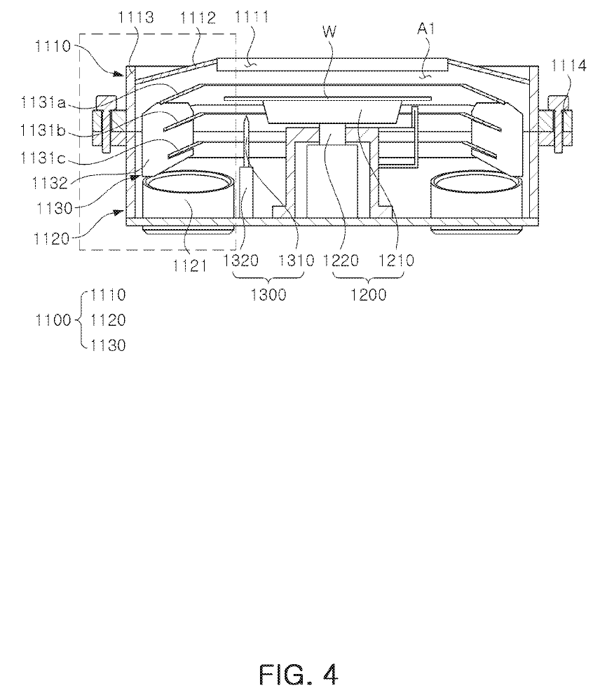

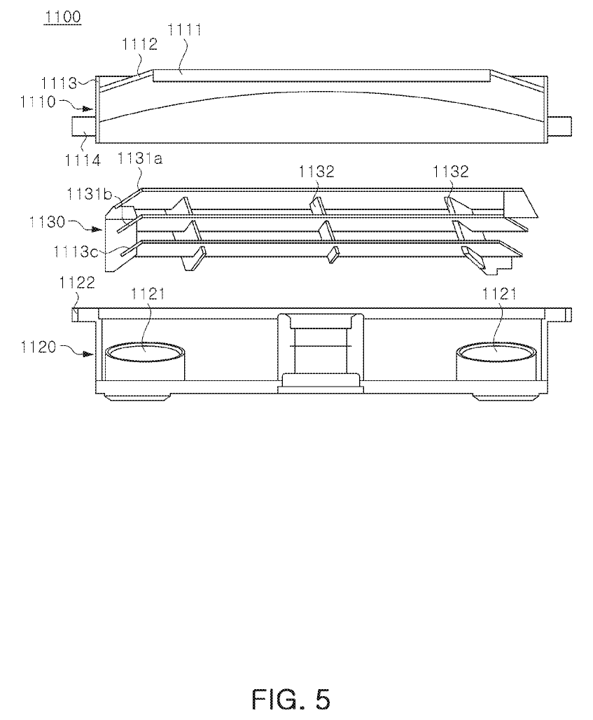

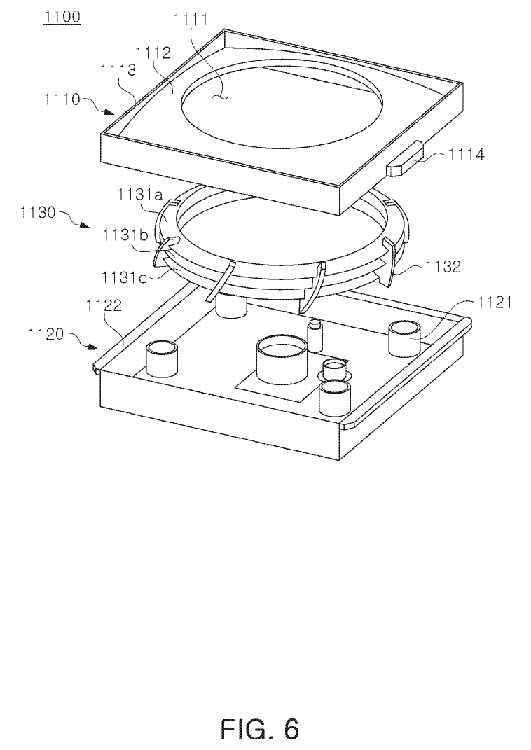

FIG. 4 is a schematic front cross-sectional view of a substrate treatment apparatus according to an example embodiment of the present disclosure. FIGS. 5 and 6 are schematic exploded views of a treatment container according to an example embodiment of the present disclosure.

Referring to FIGS. 4 to 6, a substrate treatment apparatus according to an example embodiment of the present disclosure may include a treatment container 1100, a support portion 1200, and a cleaning unit 1300.

The treatment container 1100 may have an internal space A1. In the internal space A1, the support portion 1200 and the cleaning unit 1300 may be disposed to clean a rear surface of a substrate W. A detailed structure of the treatment container 1100 will be described below.

The support portion 1200 may be provided in the internal space A1 of the treatment container 1100 to support the substrate W, and may rotate the substrate W in a rotational direction. In an example embodiment, the support portion may rotate the substrate W in a clockwise direction or in a counterclockwise direction.

In an example embodiment, the support portion 1200 may support and rotate the substrate W in the treatment container 1100. The support portion 1200 may include a support plate 1210 supporting the substrate W, and a driving member 1220 rotating the support plate 1210. In an example embodiment, a pin, supporting the substrate W, may be provided on an upper surface of the support plate 1210.

In an example embodiment, the support portion may further include an edge support unit (not illustrated) supporting an edge region of the substrate W. In addition, a central portion of the substrate W may be supported by the support plate 1210, and an edge portion of the substrate W may be supported by the edge support unit (not illustrated).

The cleaning unit 1300 may be provided in the internal space A1 of the treatment container 1100 to spray a treatment liquid toward a rear surface of the substrate W.

The cleaning unit may be disposed on one side of the support portion in the internal space A1 of the treatment container 1100 to supply the treatment liquid toward a center region of the rear surface of the substrate W.

In an example embodiment, the cleaning unit may include a nozzle 1310 spraying the treatment liquid and a nozzle support portion 1320 supporting the nozzle.

In an example embodiment, the treatment liquid may be a cleaning liquid such as deionized water. The nozzle support portion may be fixed or movable. For example, when the nozzle support portion is movable, the nozzle may perform rotational motion from a central region to an edge region of the rear surface of the substrate W or may move vertically and horizontally to clean the rear surface of the substrate W.

The treatment container 1100 may serve as a portion in which an airflow including a liquid scattered from the substrate W and fume is recovered, and the treatment container 1100 may include an upper cup 1110, a lower cup 1120, and a vortex prevention unit 1130.

In an example embodiment, the treatment liquid supplied onto the substrate W may be scattered by rotation of the substrate W. A portion of the scattered treatment liquid may collide with an upper surface 1112 of the upper cup or with a plurality of blade layers 1131a, 1131b, 1131c of the vortex prevention unit 1130, and may flow to a lower surface of the lower cup 1120.

The upper cup 1110 may be coupled to the lower cup 1120 to form the internal space A1. More specifically, the upper cup 1110 may have an open lower portion, and may have an upper central portion having an opening 1111. The treatment container 1100 may have a rectangular parallelepiped shape, and the lower surface of the lower cup 1120 may have a rectangular shape.

An open lower surface and four side walls 1113 of the upper cup 1110 may have a rectangular shape. The upper cup 1110 may include four side walls 1113 disposed to protrude along a rectangular periphery thereof, and an upper surface 1112 formed to be inclined downwardly from the opening 1111 toward the side walls 1113.

The upper surface 1112 of the upper cup 1110 may have an inclined shape having a predetermined inclination so as to rise upwardly from the side walls 1113 of the upper cup 1110, and a circular opening 1111 may be provided in the center of the upper surface 1112 to allow the substrate W to enter and exit.

In other words, the lower surface of the upper cup 1110 may be formed as a rectangular open surface. The upper surface 1112 of the upper cup 1110 may have an opening 1111 formed in the center thereof, and the upper surface 1112 may be formed to rise from the side walls 1113 of the upper cup 1110 to the opening 1111 with a predetermined inclined surface. The four side walls 1113 of the upper cup 1110 may be formed such that upper portions thereof partially protrude.

The upper surface 1112 of the upper cup 1110 may be formed to have a predetermined inclined surface, the treatment liquid scattered in the internal space A1 may collide with the upper surface 1112 and may be easily recovered into the treatment container 1100 along the inclined surface.

The lower cup 1120 may include a rectangular lower surface and four rectangular side walls, and may have a rectangular upper surface that is open.

The lower cup 1120 may have an exhaust port 1121 for exhausting an airflow in the internal space A1 or the treatment liquid.

In an example embodiment, the exhaust port 1121 may be formed at each of four corner portions of the lower surface of the lower cup 1120, and a total of four exhaust ports 1121 may be formed on the lower surface of the lower cup 1120. The exhaust port 1121 may exhaust mist in the treatment apparatus to the outside.

When the treatment container 1100 has a rectangular parallelepiped shape, the exhaust port 1121 may not be formed at each of rectangular corner portions. In this case, a sprayed mist-type scattering treatment liquid may stagnate at the rectangular corner portions and contaminate the upper surface of the substrate W.

According to an example embodiment of the present disclosure, the exhaust port 1121 may be formed at each of the four corner portions of the lower surface of the lower cup 1120 of the treatment container 1100, such that an airflow stagnated at the rectangular corner portions of the treatment container 1100 may be easily exhausted, thereby reducing contamination of the upper surface of the substrate W.

The vortex prevention unit 1130 may be disposed between the upper cup 1110 and the lower cup 1120. The vortex prevention unit 1130 may be formed in an annular ring structure including a plurality of blade layers 1131 disposed between the upper cup 1110 and the lower cup 1120 such that the treatment liquid sprayed from the cleaning unit may be effectively recovered from the inside of the treatment container 1100.

When the substrate W rotates in the treatment container 1100, a vortex may occur. The vortex prevention unit 1130 may suppress the occurrence of a vortex in the internal space A1 to prevent contamination of the upper surface of the substrate.

For example, the treatment liquid scattered in the treatment container 1100 may collide with a blade surface of the vortex prevention unit 1130 and aggregate, flow along the inclined blade surface to the lower surface of the lower cup 112 and then be exhausted to the outside through the exhaust port 1121 formed in the lower cup 112.

The vortex prevention unit 1130 may include a plurality of blade layers 1131 and fixing members 1132.

For example, each of the plurality of blade layers 1131 may be formed in a ring shape in a multi-stage structure. In the plurality of blade layers 1131, an outer radius of a lower layer may be less than an outer radius of an upper layer. That is, a radius of a blade layer of a lower stage may be formed to be less than a radius of a blade layer of an upper stage, such that the radius may be formed to gradually decrease from the upper stage to the lower stage.

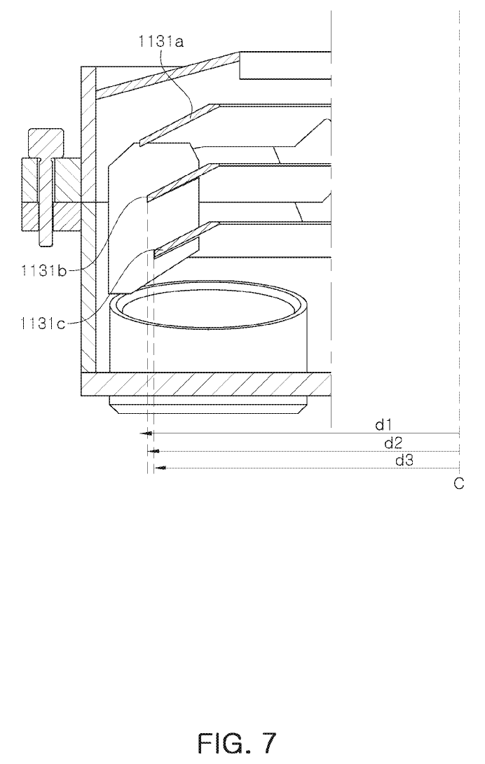

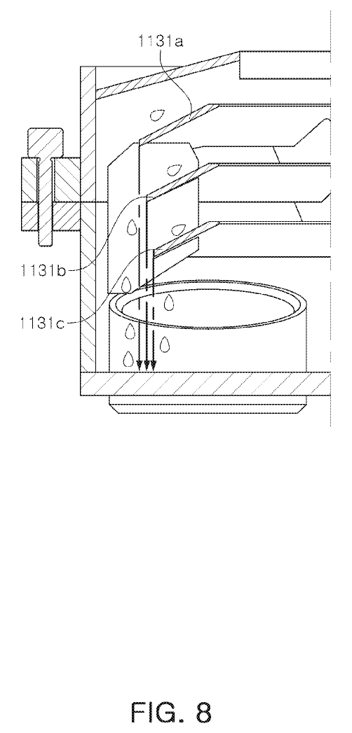

FIGS. 7 and 8 are enlarged views of a portion of FIG. 4 indicated by a dotted line.

In an example embodiment, referring to FIG. 7, the plurality of blade layers may include a first blade layer 1131a having a ring shape, a second blade layer 1131b disposed on a lower portion of the first blade layer, the second blade layer 1131b having a ring shape, and a third blade layer 1131c disposed on a lower portion of the second blade layer. An outer radius (d1) of the first blade layer may be greater than an outer radius (d2) of the second blade layer, and the outer radius (d2) of the second blade layer may be greater than an outer radius (d3) of the third blade layer. In this case, the outer radius of the blade layer may refer to a length from a central point (C) of the ring-shaped blade layer to an outermost point of the blade layer.

When the radii of the plurality of blade layers 1131 are equal to each other, water droplets falling from the upper stage may collide with the lower stage.

Referring to FIG. 8, a radius of a blade layer of the upper stage may be formed to be greater than a radius of a blade layer of the lower stage, such that water droplets falling from the upper stage may not collide with the blade layer of the lower stage. Accordingly, the water droplets falling from the upper stage may be prevented from colliding with the lower stage again and from being scattered, and the treatment liquid may be effectively recovered.

Respective ring sizes of the plurality of blade layers 1131 may be different from each other, thereby preventing vortices occurring in different directions.

Each of the plurality of blade layers 1131 may have a ring shape formed of a band having a predetermined inclination. The blade layer may be inclined to have a predetermined inclination, such that the treatment liquid colliding with one surface of the blade layer may gather and aggregate in one direction along the inclined surface.

In an example embodiment, the plurality of blade layers 1131 may be formed at an angle 10° to 30°. Each blade layer may be formed to be inclined downwardly from a central portion thereof toward an outer portion thereof. Each blade layer may be formed to be inclined with an inclination, such that the treatment liquid scattered in the treatment container 1100 may collide with the blade layer, flow down along the inclined surface, and fall to the lower surface of the lower cup 1120.

The fixing member 1132 may intersect the plurality of blade layers 1131 stacked in a vertical direction to fix the plurality of blade layers 1131.

More specifically, a plurality of fixing members 1132 may be disposed in a circumferential direction of the plurality of blade layers 1131. The fixing member 1132 may serve to maintain the plurality of blade layers 1131 in shape at predetermined intervals, and may serve to fix the vortex prevention unit 1130 between the upper cup 1110 and the lower cup 1120.

In addition, the fixing member 1132 may have a lower end biased in a rotational direction, and thus may have a predetermined inclination.

For example, when the substrate W rotates in a clockwise direction, a lower end of the fixing member 1132 may be biased in a clockwise direction. Alternatively, when the substrate W rotates in a counterclockwise direction, the lower end of the fixing member 1132 may be biased in a counterclockwise direction.

In an example embodiment, when the substrate W rotates in a clockwise direction, the treatment liquid attached to the substrate W may be dispersed in the form of a clockwise vortex on a plane of the substrate W.

When the lower end of the fixing member 1132 is biased in a rotational direction of the substrate W, the treatment liquid dispersed in a direction of the plane of the substrate W may collide with the fixing member 1132 and be reflected downwardly, thereby preventing regeneration of a vortex and more effectively recovering the treatment liquid.

A fixing unit 1114 protruding from a lower portion of the upper cup 1110 may be provided, and a fixing unit 1122 protruding from an upper portion of the lower cup 1120 may be provided, such that the upper cup 1110 and the lower cup 1120 may be connected and fixed to each other by a connection member.

While example embodiments have been shown and described above, it will be apparent to those skilled in the art that modifications and variations could be made without departing from the scope of the present disclosure as defined by the appended claims.

What is claimed is:

1. A substrate treatment apparatus comprising:
a treatment container having an internal space;
a support portion provided in the internal space, the support portion configured to support the substrate; and
a cleaning unit provided in the internal space, the cleaning unit configured to spray a treatment liquid toward a rear surface of the substrate,
wherein the treatment container includes:
a lower cup having a lower surface having a rectangular shape and an open upper portion;
an upper cup coupled to the lower cup to form the internal space; and
a vortex prevention unit disposed between the lower cup and the upper cup, and
the vortex prevention unit includes a plurality of blade layers in which an outer radius of a lower layer is less than an outer radius of an upper layer.

2. The substrate treatment apparatus of claim 1, wherein each of the plurality of blade layers has a ring shape formed of a band having a predetermined inclination.

3. The substrate treatment apparatus of claim 1, wherein
the plurality of blade layers include:
a first blade layer having a ring shape; and
a second blade layer disposed on a lower portion of the first blade layer, the second blade layer having a ring shape, and
an outer radius of the first blade layer is greater than an outer radius of the second blade layer.

4. The substrate treatment apparatus of claim 1, wherein each of the plurality of blade layers is formed to be inclined downwardly from a central portion thereof toward an outer portion thereof.

5. The substrate treatment apparatus of claim 1, wherein
the vortex prevention unit further includes a fixing member intersecting with the plurality of blade layers stacked in a vertical direction, the fixing member configured to fix the plurality of blade layers, and
the fixing member is disposed in a circumferential direction of the plurality of blade layers.

6. The substrate treatment apparatus of claim 5, wherein
the support portion rotates the substrate in a rotational direction, and
the fixing member has a lower end biased in the rotational direction, and thus has a predetermined inclination.

7. The substrate treatment apparatus of claim 1, wherein the lower cup includes an exhaust port for exhausting an airflow in the internal space or a treatment liquid.

8. The substrate treatment apparatus of claim 7, wherein
a lower surface of the lower cup has a rectangular shape, and
the exhaust port is formed at each of four corner portions of the lower surface of the lower cup.

9. The substrate treatment apparatus of claim 1, wherein the support portion further includes an edge support unit supporting an edge portion of the substrate.

10. The substrate treatment apparatus of claim 1, wherein the upper cup has an open lower portion, and an upper central portion having an opening, and includes four side walls disposed along a rectangular periphery thereof, and an upper surface formed to be inclined downwardly from the opening toward the side walls.

11. A treatment container having an internal space, the treatment container comprising:
a lower cup having a lower surface having a rectangular shape and an open upper portion;
an upper cup coupled to the lower cup to form the internal space; and
a vortex prevention unit disposed between the lower cup and the upper cup,
wherein the vortex prevention unit includes a plurality of blade layers, and
the vortex prevention unit includes a plurality of blade layers in which an outer radius of a lower layer is less than an outer radius of an upper layer.

12. The treatment container of claim 11, wherein each of the plurality of blade layers has a ring shape formed of a band having a predetermined inclination.

13. The treatment container of claim 11, wherein
the plurality of blade layers include:
a first blade layer having a ring shape; and
a second blade layer disposed on a lower portion of the first blade layer, the second blade layer having a ring shape, and
an outer radius of the first blade layer is greater than an outer radius of the second blade layer.

14. The treatment container of claim 11, wherein each of the plurality of blade layers is formed to be inclined downwardly from a central portion thereof toward an outer portion thereof.

15. The treatment container of claim 11, wherein
the vortex prevention unit further includes a fixing member intersecting the plurality of blade layers stacked in a vertical direction, the fixing member configured to fix the plurality of blade layers, and
the fixing member is disposed in a circumferential direction of the plurality of blade layers.

16. The treatment container of claim 15, wherein the fixing member has a lower end biased in a rotational direction in which a substrate rotates, and thus has a predetermined inclination.

17. The treatment container of claim 11, wherein the lower cup includes an exhaust port for exhausting an airflow in the internal space or a treatment liquid.

18. The treatment container of claim 17, wherein the exhaust port is formed at each of four corner portions of the lower surface of the lower cup.

19. The treatment container of claim 11, wherein the upper cup has an open lower portion, and an upper central portion having an opening, and includes four side walls disposed along a rectangular periphery thereof, and an upper surface formed to be inclined downwardly from the opening toward the side walls.

20. A substrate treatment apparatus comprising:
a treatment container having an internal space;
a support portion provided in the internal space, the support portion configured to support a substrate; and
a cleaning unit provided in the internal space, the cleaning unit configured to spray a treatment liquid toward a rear surface of the substrate,
wherein the treatment container includes:
a lower cup having a lower surface having a rectangular shape and an open upper portion;
an upper cup coupled to the lower cup to form the internal space; and
a vortex prevention unit disposed between the lower cup and the upper cup, and
the vortex prevention unit includes:
a plurality of blade layers in which an outer radius of a lower layer is less than an outer radius of an upper layer, each of the plurality of blade layers formed of a band having a predetermined inclination, the band inclined downwardly from a central portion thereof toward an outer portion thereof; and
a fixing member intersecting the plurality of blade layers stacked in a vertical direction, the fixing member configured to fix the plurality of blade layers, and
the fixing member has a lower end biased in a rotational direction of the substrate, and thus has a predetermined inclination.
